(19) United States
(12) Patent Application Publication
(10) Pub. No.: US 2025/0280514 A1
(43) Pub. Date: Sep. 4, 2025

(54) SYSTEMS AND METHODS FOR VARIABLE TEMPERATURE DATACENTER ARCHITECTURE

(71) Applicant: Microsoft Technology Licensing, LLC, Redmond, WA (US)

(72) Inventors: Husam Atallah ALISSA, Redmond, WA (US); Ruslan NAGIMOV, Redmond, WA (US)

(21) Appl. No.: 18/594,633

(22) Filed: Mar. 4, 2024

(51) Int. Cl. H05K 7/20; G06F 1/20

(52) U.S. Cl. CPC H05K 7/20372; G06F 1/206; H05K 7/20818

(57) ABSTRACT

A system may include a processor core. A system may include a memory device. A system may include a conduit having a flow direction and configured to receive heat from the processor core and the memory device a refrigeration system in series. A system may include a working fluid located in the conduit and configured to receive the heat through the conduit to cool the processor core. A system may include a refrigeration system configured to exhaust heat from the working fluid and cool the working fluid to a lower-than-ambient temperature. A system may include a workload controller in data communication with the refrigeration system and configured to instruct the refrigeration system to cool the processor core to a processor temperature based at least partially on a workload demand.

### BACKGROUND

Thermal management of electronic components has long been a limitation to computing performance. Cryogenic cooling can allow greater performance, but a greater amount of cooling consumes a greater amount of electrical power.

### BRIEF SUMMARY

In some aspects, the techniques described herein relate to a thermal management system including: a processor core; a memory device; a conduit having a flow direction and configured to receive heat from the processor core and the memory device a refrigeration system in series; a working fluid located in the conduit and configured to receive the heat through the conduit to cryogenically cool the processor core; a refrigeration system configured to exhaust heat from the working fluid and cool the working fluid to a cryogenic temperature; and a workload controller in data communication with the refrigeration system and configured to instruct the refrigeration system to cool the processor core to a processor temperature based at least partially on a workload demand.

In some aspects, the techniques described herein relate to a method of operating a datacenter, the method including: obtaining a workload demand; determining at least a processor temperature based at least partially on the workload demand; changing a cooling capacity of a refrigeration system at a processor core based at least partially on the processor temperature; and selecting the processor core having a threshold voltage from a plurality of processor cores based at least partially on the processor temperature.

In some aspects, the techniques described herein relate to a method of operating a datacenter, the method including: obtaining a workload demand; determining at least a processor temperature based at least partially on the workload demand; changing a cooling capacity of a refrigeration system at a processor core based at least partially on the processor temperature; selecting a computing component having a threshold voltage from a plurality of computing components of a same type based at least partially on a residual cooling capacity of a working fluid downstream in a flow direction of the working fluid from the processor core; and directing communication between the processor core and a selected computing component.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 illustrates a graph of processing power of various processing units relative to time.

FIG. 2 is a graph illustrating a plot of gigaflops per Watt of electrical power of an embodiment of a central processing unit (CPU) that is clocked or overclocked to different operating frequencies.

FIG. 3 is a graph illustrating the computing power per Watt normalized to a control processing unit operating at ambient temperature.

FIG. 4 is a graph illustrating the computing PPW normalized to the processing unit operating at a control ambient temperature when the electrical power consumption to cool the processing unit to the given temperatures is considered.

FIG. 5 is a schematic illustration of a variable-temperature thermal management system configured to cool computing components, according to at least one embodiment of the present disclosure.

FIG. 6 is a schematic illustration of a variable-temperature thermal management system configured to cool computing components in series including graphical processing unit cores and central processing unit cores, according to at least one embodiment of the present disclosure.

FIG. 7 is a flowchart illustrating a method of operating a datacenter, according to at least one embodiment of the present disclosure.

FIG. 8 is a flowchart illustrating another method of operating a datacenter, according to at least one embodiment of the present disclosure.

FIG. 9 is a schematic illustration of a variable-temperature thermal management system with a plurality of selectable computing components of the same type, according to at least one embodiment of the present disclosure.

FIG. 10 is a schematic illustration of a variable-temperature thermal management system with a plurality of cooling circuits, according to at least one embodiment of the present disclosure.

### DETAILED DESCRIPTION

The present disclosure relates generally to systems and methods for cooling computing components. More particularly, the present disclosure relates to cooling of computing packages and components at a variety of temperatures. In some embodiments, a thermal management system allows for selective cryogenic cooling of some components of a computing system. In some embodiments, systems and methods according to the present disclosure can select computing components from a plurality of computing components wherein the selected computing components are selected based at least partially on a threshold voltage of the components and a current or expected component temperature during processing. Reconfigurable computing systems and variable cooling of the computing components allows a datacenter to adapt to the workload demands received to provide the highest performance and/or most efficient processing power.

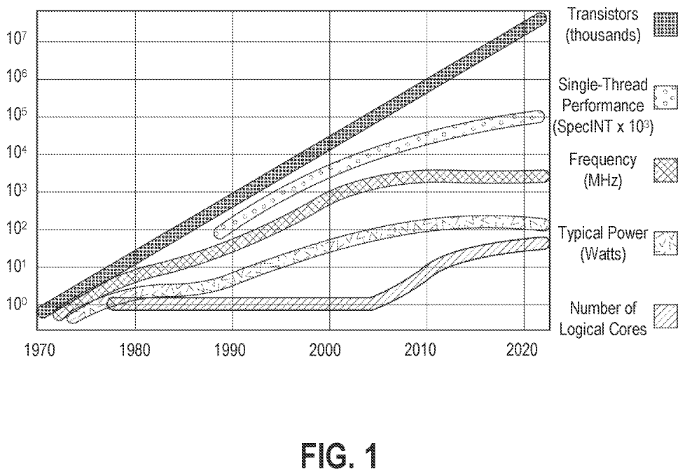

FIG. 1 illustrates a graph 100 of processing power of various processing units relative to time. Through the Dennard's Scaling Era, processing power increased commensurately with the density of transistors on a die and increases in the operating frequency of the processing unit. This era primarily saw increases in performance in single-core systems by inputting increasing amounts of electrical power into the processing unit to achieve more processing power.

As multi-core processing units were developed in the mid-2000s, additional processing performance gains were realized with substantially constant operating frequency. Power consumption of the processing unit continued to increase as the multi-core architecture continued the processing unit to perform additional processes in parallel on the different cores. With increases in electrical power and increases in transistor density, processing power has become limited by the density of electrical power used in the processing units. In some embodiments, the processing units dissipate a portion of the electrical power used by the processing unit as heat in the system, limiting the operating frequency and limiting the proportion of the processing unit that may be actively performing calculations at any time.

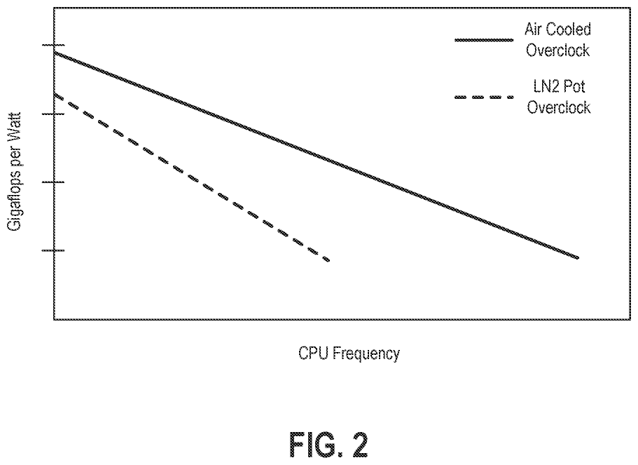

FIG. 2 is a graph 200 illustrating a plot of gigaflops (i.e., billions of floating-point calculations per second) per Watt of electrical power of an embodiment of a central processing unit (CPU) that is clocked or overclocked to different operating frequencies. As the CPU frequency increases, the gigaflops are observed to increase, but an associated increase in electrical power consumption by the CPU produces a decrease in gigaflops per watt of electrical power consumed.

The graph also illustrates a plot of gigaflops per Watt for the same CPU that is cryogenically-cooled. In the illustrated embodiment, the CPU is cooled with liquid nitrogen to approximately 77 K (−196° C.). The CPU exhibits increased processing power (in gigaflops) relative to an equivalent operating frequency of the CPU that is air-cooled. In some examples, the CPU also exhibits increased efficiency at a 4.8 gigahertz (GHz) operating frequency when cryogenically-cooled relative to the CPU at the same frequency when air-cooled. Further, as compared to when air-cooled, the CPU exhibits the same efficiency (gigaflops per Watt) overclocked to 5.8 GHz when cryogenically-cooled.

Cryogenic cooling includes, in some embodiments according to the present disclosure, the cooling of computing components to a lower-than-ambient temperature. In some embodiments, cryogenic cooling includes the cooling of computing components below 20° C. In some embodiments, cryogenic cooling includes the cooling of computing components below 0° C. In some embodiments, cryogenic cooling includes the cooling of computing components below −50° C. In some embodiments, cryogenic cooling includes the cooling of computing components below −100° C. In some embodiments, cryogenic cooling includes the cooling of computing components below −150° C. In some embodiments, cryogenic cooling includes the cooling of computing components below approximately 77 K (−196° C.). In some embodiments, cryogenic cooling includes the cooling of computing components with liquid nitrogen.

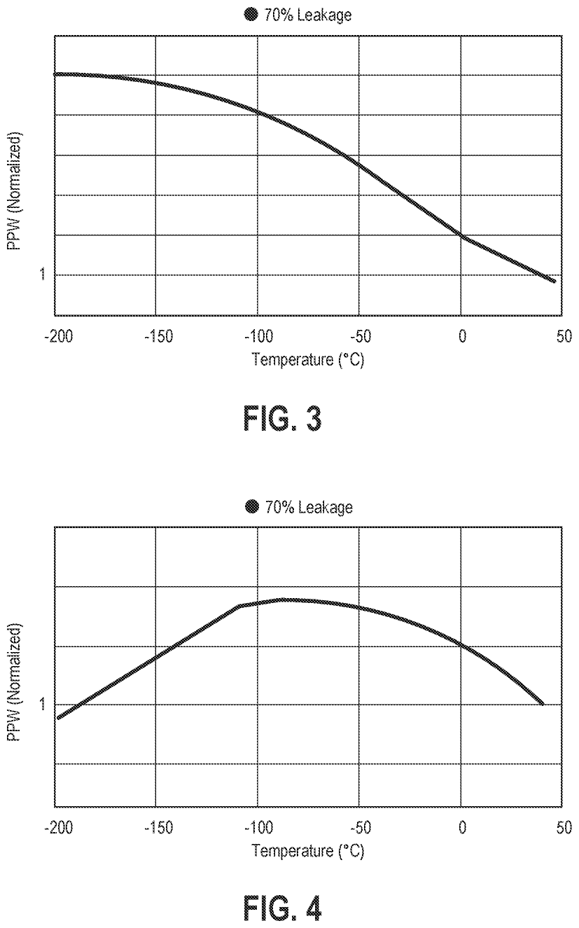

FIG. 3 is a graph 300 illustrating the computing power per Watt normalized to a control processing unit operating at ambient temperature. The computing power per Watt at ambient temperature is measured from the processing unit when air-cooled. The computing power per Watt is measured at a consistent operating frequency throughout the graph illustrated in FIG. 3. The static dissipated power can be reduced by reducing the leakage power. The dynamic dissipated power can, in turn, be reduced by reducing the supply voltage (which is dependent on the threshold voltage V_{T} of the transistors of the device).

At fixed threshold voltage V_{T}, leakage power is exponentially dependent on temperature. The temperature therefor affects the power consumption for the logic gates exponentially, and this effect becomes a prevailing effect in processing units with a greater proportion of the power dissipation due to P_{leakage}, which provides a decrease in static dissipated power. A reduction in temperature also allows a reduction in threshold voltage, which allows a reduction in supply voltage, decreasing the dynamic dissipated power. In the datacenter, the threshold voltage for a device is constant, however, so changing the threshold voltage may include changing the computing component, such as by selecting a component from a plurality of components based on a current or expected temperature of the component during a workload.

The processing unit exhibits increases in processing power per Watt (PPW) as the temperature decreases. In some embodiments, such as the processing unit tested in FIG. 3, the performance increases exhibit diminishing returns at different temperatures depending on the leakage percentage, with the highest leakage percentage exhibiting greatest PPW increases down to at least a liquid nitrogen boiling temperature at one atmosphere of pressure. Other leakage percentages exhibit diminishing returns in PPW gains at higher temperatures, but all show increases in PPW relative to operating at an ambient temperature.

Cooling the processing unit consumes electrical power, however, and cryogenic cooling of the processing unit consumes more power than ambient cooling. FIG. 4 is a graph 400 illustrating the computing PPW normalized to the processing unit operating at a control ambient temperature when the electrical power consumption to cool the processing unit to the given temperatures is considered. The computing PPW at ambient temperature is measured from the processing unit when air-cooled using a conventional air-cooled heatsink. The computing PPW is measured at a consistent operating frequency throughout the graph illustrated in FIG. 4.

Additional electrical power consumed to cool the components results in diminishing returns below approximately −50° C. to 100° C., depending on the operating conditions of the processing unit. However, gains are still realized at the higher leakage operating conditions down to approximately a liquid nitrogen boiling temperature. In some embodiments, other components can benefit from the cryogenic cooling of one or more components. For example, residual cooling capacity of the thermal management system can conduct heat away from other components in the same or neighboring cooling circuit.

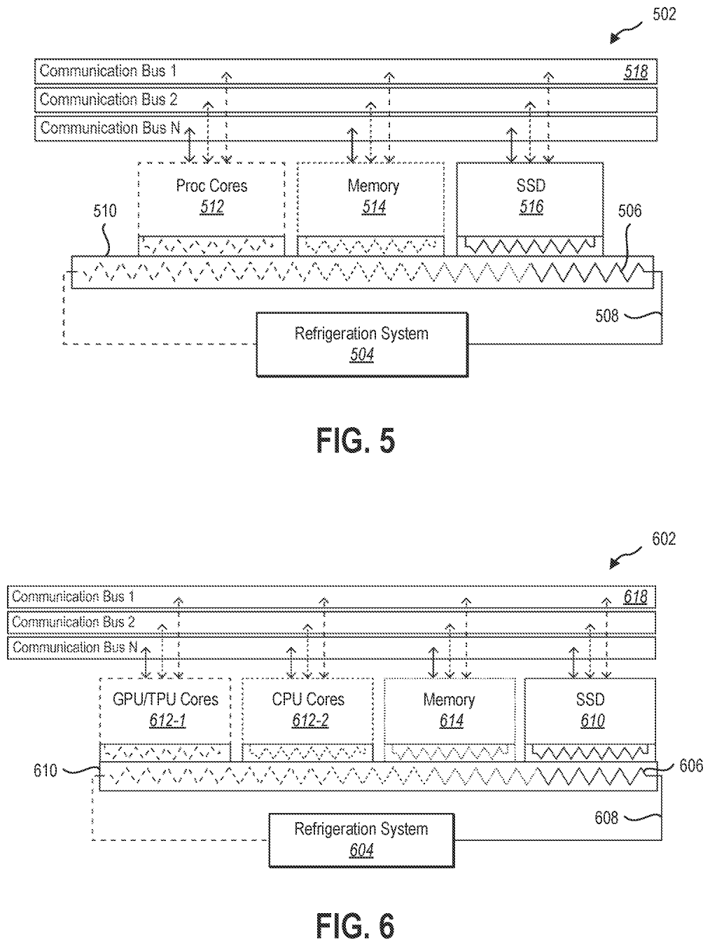

FIG. 5 is a schematic illustration of an embodiment of a variable-temperature thermal management system 502 configured to cool computing components. In some embodiments, the thermal management system 502 includes a refrigeration system 504 that exhausts heat from a working fluid 506 that circulates through one or more conduits 508 and/or heat exchangers 510. The thermal management system 502, in some embodiments, cools one or more of processing cores 512, memory devices 514, storage devices 516 (such as solid-state drives), or other heat-generating components. The working fluid 506 receives heat from the heat-generating components, which increases the temperature of the working fluid 506 and reduces the temperature of the heat-generating components. The working fluid 506 circulates through the thermal management system 502 to the refrigeration system 504, which exhausts the heat from the working fluid 506.

In some embodiments, the working fluid 506 is or includes a two-phase working fluid that receives heat and changes state without a substantial change in temperature. In some embodiments, the working fluid 506 is or includes liquid nitrogen. In some embodiments, the working fluid 506 is or includes other fluids. For example, other working fluids 506 may be or include conventional refrigerants, liquid CO₂, liquefied hydrocarbons, liquid argon, liquid methane, gaseous nitrogen, gaseous helium, or combinations thereof.

In some embodiments, the computing components are in data communication with one another through a communication bus 518 or plurality of communication buses that allow each computing component of each type of computing component (e.g., processing cores 512, memory devices 514, storage devices 516, etc.) to communicate with computing components of each other type of computing component. For example, the communication bus 518 allows each of the processing cores 512 to communicate with any of the memory devices 514 and any of the storage devices 516.

In some embodiments, different processing cores 512 of the plurality of processing cores 512 have different threshold voltages (V_{T}), such that different processing cores 512 have different PPW efficiencies at different temperatures. In some embodiments, a processing core 512 is selected based on a requested workload and the processing demands on the system. For example, a workload that is highly processing intensive (such as a machine learning model training task) justifies cryogenic cooling of the processing core(s) 512 for increased performance, even when that cryogenic cooling increases power consumption from the thermal management system. In some embodiments, cryogenic cooling of a processing core 512 requires the working fluid 506 be cooled to cryogenic temperatures and, even after receiving heat from the processing core(s) 512, the working fluid 506 is still at cryogenic temperatures. The working fluid 506 has residual cooling capacity that is used to cool the memory device(s) 514 and/or the storage devices 516.

As will described in more detail herein, in some embodiments, the computing system can select a memory device 514 from a plurality of memory devices 514 and/or a storage device 516 from a plurality of storage devices 516 based at least partially on residual cooling capacity of the working fluid 506 after cooling the processing core(s) 512. In at least one example, a requested workload is processing intensive, and a processing core 512 is cryogenically cooled to a processor temperature (T_{PROC}) by the thermal management system 502. The computing system selects a memory device 514 with a V_{T.MEM} based at least partially on the residual cooling capacity of the working fluid 506 after cooling the processing core(s) 512 that allows cooling of the memory device 514 to a memory temperature (T_{MEM}). By selecting a memory device 514 based on the T_{MEM} produced by the residual cooling capacity after cooling the processor core(s) 512 to T_{PROC}, the selected memory device(s) 514 have properties (e.g., V_{T.MEM}) that allow the selected memory device(s) 514 to operate efficiently (PPW) and/or quickly (e.g., bandwidth) at the T_{MEM}. Similarly, by selecting a storage device 516 based on the T_{SSD} produced by the residual cooling capacity after cooling the memory device(s) 514 to T_{MEM}, the selected storage device(s) 516 have properties (e.g., V_{T.SSD}) that allow the selected storage device(s) 516 to operate efficiently (PPW) and/or quickly (e.g., bandwidth) at the T_{SSD}. The communication buses 518 allow communication between any of the computing components with other computing components of other types, allowing a processing core 512 to communicate with the selected memory device(s) 514 and/or selected storage device(s) 516 to dynamically configure computing systems that more or most efficiently operate at different temperatures.

In some embodiments, the types of computing components (e.g., processing cores 512, memory devices 514, storage devices 516, etc.) are cooled in series with the computing components demanding the greatest cooling capacity positioned earlier in the series (i.e., closer to the refrigeration system 504) in flow direction of the working fluid 506 through the thermal management system 502. In some embodiments, different computing components within a type of computing component can have different operating temperatures or efficient operating temperatures. In some embodiments, the different operating temperatures or efficient operating temperatures can vary by requested workload.

FIG. 6 is a schematic illustration of an embodiment of a variable-temperature thermal management system 602 configured to cool computing components in series including graphical processing unit (GPU) cores 612-1 and central processing unit (CPU) cores 612-2. In some embodiments, the thermal management system 602 includes a refrigeration system 604 that exhausts heat from a working fluid 606 that circulates through one or more conduits 608 and/or heat exchangers 610. The thermal management system 602, in some embodiments, cools one or more of GPU cores 612-1, CPU cores 612-2, memory devices 614, storage devices 616 (such as solid-state drives), or other heat-generating components. The working fluid 606 receives heat from the heat-generating components, which increases the temperature of the working fluid 606 and reduces the temperature of the heat-generating components. The working fluid 606 circulates through the thermal management system 602 to the refrigeration system 604, which exhausts the heat from the working fluid 606.

In some embodiments, the computing components are in data communication with one another through a communication bus 618 or plurality of communication buses that allow each computing component of each type of computing component (e.g., GPU cores 612-1, CPU cores 612-2, memory devices 614, storage devices 616, etc.) to communicate with computing components of each other type of computing component. For example, the communication bus 618 allows each of the processing cores 612 to communicate with any to the memory devices 614 and any of the storage devices 616.

In some embodiments, different GPU cores 612-1 and/or CPU cores 612-2 have different threshold voltages (V_{T}), such that different GPU cores 612-1 and/or CPU cores 612-2 have different PPW efficiencies at different temperatures. In some embodiments, a GPU core 612-1 and/or CPU core 612-2 is selected based on a requested workload and the processing demands on the system. In some embodiments, the GPU core(s) 612-1 or the CPU core(s) 612-2 are prioritized for thermal management, depending on the requested workload. For example, a workload that is GPU processing intensive (such as a machine learning model training task) may cause the system to prioritize cryogenic cooling of the GPU cores 612-1 for increased performance, even when that cryogenic cooling increases power consumption from the thermal management system. In some embodiments, cryogenic cooling of a GPU core 612-1 requires the working fluid 606 be cooled to cryogenic temperatures and, even after receiving heat from the GPU core(s) 612-1, the working fluid 606 is still at cryogenic temperatures.

In some embodiments, a requested workload that is more CPU processing intensive than GPU processing intensive may prioritize cooling of the CPU to a selected T_{CPU}. In such a case, the GPU core(s) 612-1 are cooled enough to provide residual cooling capacity to achieve the selected T_{CPU}. A GPU core 612-1 is, in some embodiments, selected with a threshold voltage at a T_{GPU} that allows the efficient operation of the CPU at the selected T_{CPU}. The working fluid 606 has residual cooling capacity that is used to cool the memory device(s) 614 and/or the storage devices 616. The communication buses 618 allow communication between any of the computing components with other computing components of other types, allowing a GPU core 612-1 to communicate with the selected CPU core 612-2, the selected memory device(s) 614, and/or the selected storage device(s) 616 to dynamically configure computing systems that more or most efficiently operate at different temperatures.

In some embodiments, the types of computing components (e.g., GPU cores 612-1, CPU cores 612-2, memory devices 614, storage devices 616, etc.) are cooled in series with the computing components demanding the greatest cooling capacity positioned earlier in the series (i.e., closer to the refrigeration system 604) in flow direction of the working fluid 606 through the thermal management system 602. In some embodiments, different computing components within a type of computing component can have different operating temperatures or efficient operating temperatures. In some embodiments, the different operating temperatures or efficient operating temperatures can vary by requested workload.

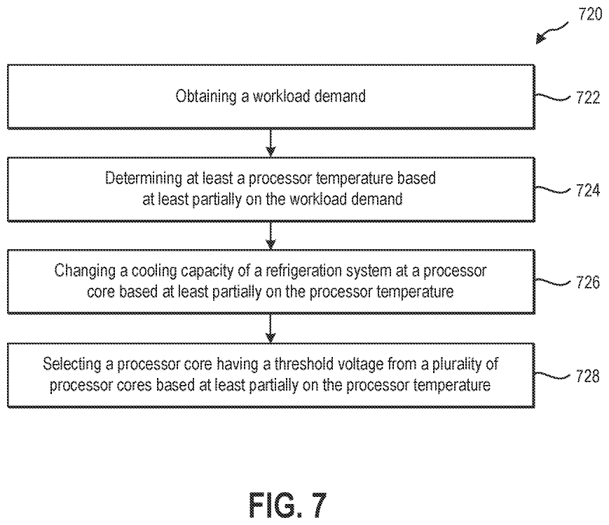

FIG. 7 is a flowchart illustrating an embodiment of a method 720 of operating a datacenter. In some embodiments, the method 720 includes obtaining a workload demand at 722. In some embodiments, the workload demand is obtained from an allocator or other workload management controller. In some embodiments, the workload demand is received from an allocator or other workload management controller in the datacenter, such as local to the computing devices processing the workload and cooled by a variable-temperature thermal management system. In some embodiments, the workload demand is received from an allocator or other workload management controller external to the datacenter, such as remote to the computing devices processing the workload and cooled by a variable-temperature thermal management system. In some embodiments, the allocator or other workload management controller is located in another datacenter or that is in data communication with the datacenter or co-location including the computing devices processing the workload and cooled by a variable-temperature thermal management system.

In some embodiments, the workload demand is obtained by a workload controller, as will be described in more detail herein. The workload controller is, in some embodiments, in data communication with at least some of the computing components of the datacenter. The workload controller is, in some embodiments, in data communication with at least some components of the variable-temperature thermal management system, such as a refrigeration system, heat exchangers, one or more valves, etc.

The method 720 further includes determining at least a processor temperature based at least partially on the workload demand at 724. In some embodiments, the allocator or other workload management controller provides or determines the processor temperature. In some embodiments, the workload controller provides or determines the processor temperature. For example, determining at least a processor temperature based at least partially on the workload demand may include comparing the workload demand or workload demand type to a table or other file of expected processing loads. In some embodiments, a processor temperature is determined at least partially on a known or expected workload duration. For example, cryogenically-cooling the processor core(s) may provide greater efficiency and/or speed gains when the duration of the workload is longer, as the initial cooling of the processor core(s) to the cryogenic temperatures consumes power. In some embodiments, the processor temperature is determined at least partially on a known or expected processor load. For example, the computing system may include GPUs that have a greater PPW gain at cryogenic temperatures than CPUs of the computing system. The processor temperature may be determined at least partially on the PPW efficiency and/or processing speed gains of the type of processors.

In some embodiments, the workload demand or workload demand type is known or expected to place a greater computational demand on a GPU or on a CPU of the computing system. In at least one example, the method 720 may include determining a first processor temperature for a GPU-intensive workload while a CPU-intensive workload may be determined to prioritize a different processor temperature. In some embodiments, determining at least a processor temperature based at least partially on the workload demand includes determining a GPU temperature. In some embodiments, determining at least a processor temperature based at least partially on the workload demand includes determining a CPU temperature. In some embodiments, determining at least a processor temperature based at least partially on the workload demand includes selecting a lower processor temperature of the CPU temperature and the GPU temperature. In some embodiments, determining at least a processor temperature based at least partially on the workload demand includes determining a memory device temperature. For example, the memory device temperature may be determined based at least partially on a residual cooling capacity in series from the processor temperature. In some embodiments, determining at least a processor temperature based at least partially on the workload demand includes determining a storage device temperature. For example, the storage device temperature may be determined based at least partially on a residual cooling capacity in series from the processor temperature and/or memory device temperature.

The method 720 further includes changing a cooling capacity of a thermal management system at a processor core based at least partially on the processor temperature at 726. The thermal management system includes a refrigeration system that exhausts heat from a working fluid, as described herein at least in relation to FIG. 5 and FIG. 6. In some embodiments, the changing a cooling capacity of a thermal management system includes changing at least one operating condition of the refrigeration system, such as a flow rate of working fluid through the refrigeration system and/or a compressor rate compressing the working fluid. In some embodiments, changing at least one operating condition of the refrigeration system includes changing an exhaust rate of the refrigeration system, such as enabling a fan or other active heat exhaustion device to exhaust heat from the refrigeration system to the ambient atmosphere or other heat sink.

In some embodiments, changing a cooling capacity of the thermal management system includes changing a flow path of the working fluid through the thermal management system. For example, the thermal management system may include a plurality of fluid circuits through one or more heat exchangers and/or include a dewar or storage tank of additional working fluid to change and/or provide additional thermal mass to the working fluid of the thermal management system. In some embodiments, changing a flow path of the working fluid includes flowing a second working fluid with a different boiling temperature and/or freezing temperature through at least a portion of the thermal management system. For example, the thermal management system may flow a first working fluid through a heat exchanger proximate to a processor core at a first processor temperature (e.g., ambient temperature) and flow a second working fluid through the heat exchanger proximate to the processor core at a second processor temperature (e.g., cryogenic temperature).

In some embodiments, the method 720 optionally includes selecting a processor core having a processor threshold voltage from a plurality of processor cores based at least partially on the processor temperature at 728. In some embodiments, the processor temperature is determined at least partially based on a processor threshold voltage. The processor threshold voltage is a property of the processor core(s). A lower processor temperature allows for a lower threshold voltage, which, in turn, allows for a lower supply voltage and greater PPW efficiency. In some examples, the same processor core with a lower threshold voltage does not operate efficiently at a higher processor temperature, such as at ambient temperature. The determined and/or selected processor temperature, therefore, allows the workload controller or other controller to select one or more processor cores having a threshold voltage based at least partially on the processor temperature.

In some embodiments, the method includes determining a GPU temperature. In such examples, selecting a processor core having a threshold voltage based on the processor temperature includes selecting a GPU core having a GPU threshold voltage based on the GPU temperature. In some examples, the method includes selecting a CPU core based at least partially on the residual cooling capacity when the CPU core is after the GPU core in series. In some examples, the method includes selecting a CPU core based at least partially on the residual cooling capacity to achieve the GPU temperature when the GPU core is after the CPU core in series.

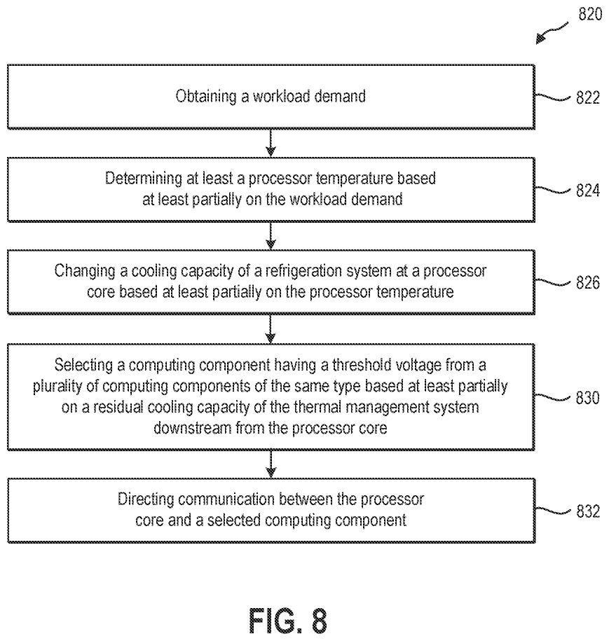

In some embodiments, the method includes selecting other computing devices based at least partially on residual cooling capacity after the targeted processor temperature. FIG. 8 is a flowchart illustrating another embodiment of a method 820 of operating a datacenter. In some embodiments, the method 820 includes obtaining a workload demand at 822. In some embodiments, the workload demand is obtained from an allocator or other workload management controller. In some embodiments, the workload demand is received from an allocator or other workload management controller in the datacenter, such as local to the computing devices processing the workload and cooled by a variable-temperature thermal management system. In some embodiments, the workload demand is received from an allocator or other workload management controller external to the datacenter, such as remote to the computing devices processing the workload and cooled by a variable-temperature thermal management system. In some embodiments, the allocator or other workload management controller is located in another datacenter or that is in data communication with the datacenter or co-location including the computing devices processing the workload and cooled by a variable-temperature thermal management system.

In some embodiments, the workload demand is obtained by a workload controller, as will be described in more detail herein. The workload controller is, in some embodiments, in data communication with at least some of the computing components of the datacenter. The workload controller is, in some embodiments, in data communication with at least some components of the variable-temperature thermal management system, such as a refrigeration system, heat exchangers, one or more valves, etc.

The method 820 further includes determining at least a processor temperature based at least partially on the workload demand at 824. In some embodiments, the allocator or other workload management controller provides or determines the processor temperature. In some embodiments, the workload controller provides or determines the processor temperature. For example, determining at least a processor temperature based at least partially on the workload demand may include comparing the workload demand or workload demand type to a table or other type of data about expected processing loads. In some embodiments, a processor temperature is determined at least partially on a known or expected workload duration. For example, cryogenically-cooling the processor core(s) may provide greater efficiency and/or speed gains when the duration of the workload is longer, as the initial cooling of the processor core(s) to the cryogenic temperatures consumes power. In some embodiments, the processor temperature is determined at least partially on a known or expected processor load. For example, the computing system may include GPUs that have a greater PPW gain at cryogenic temperatures than CPUs of the computing system. The processor temperature may be determined at least partially on the PPW efficiency and/or processing speed gains of the type of processors.

In some embodiments, the workload demand or workload demand type is known or expected to place a greater computational demand on a GPU or on a CPU of the computing system. In at least one example, the method 820 may include determining a first processor temperature for a GPU-intensive workload while a CPU-intensive workload may be determined to prioritize a different processor temperature. In some embodiments, determining at least a processor temperature based at least partially on the workload demand includes determining a GPU temperature. In some embodiments, determining at least a processor temperature based at least partially on the workload demand includes determining a CPU temperature. In some embodiments, determining at least a processor temperature based at least partially on the workload demand includes selecting a lower processor temperature of the CPU temperature and the GPU temperature. In some embodiments, determining at least a processor temperature based at least partially on the workload demand includes determining a memory device temperature. For example, the memory device temperature may be determined based at least partially on a residual cooling capacity in series from the processor temperature. In some embodiments, determining at least a processor temperature based at least partially on the workload demand includes determining a storage device temperature. For example, the storage device temperature may be determined based at least partially on a residual cooling capacity in series from the processor temperature and/or memory device temperature.

In some embodiments, the workload demand or workload demand type is known or expected to place a greater computational demand on a GPU or on a CPU of the computing system. In at least one example, the method 820 may include determining a first processor temperature for a GPU-intensive workload while a CPU-intensive workload may be determined to prioritize a different processor temperature. In some embodiments, determining at least a processor temperature based at least partially on the workload demand includes determining a GPU temperature. In some embodiments, determining at least a processor temperature based at least partially on the workload demand includes determining a CPU temperature. In some embodiments, determining at least a processor temperature based at least partially on the workload demand includes selecting a lower processor temperature of the CPU temperature and the GPU temperature. In some embodiments, determining at least a processor temperature based at least partially on the workload demand includes determining a memory device temperature. For example, the memory device temperature may be determined based at least partially on a residual cooling capacity in series from the processor temperature. In some embodiments, determining at least a processor temperature based at least partially on the workload demand includes determining a storage device temperature. For example, the storage device temperature may be determined based at least partially on a residual cooling capacity in series from the processor temperature and/or memory device temperature.

The method 820 further includes changing a cooling capacity of a thermal management system at a processor core based at least partially on the processor temperature at 826. The thermal management system includes a refrigeration system that exhausts heat from a working fluid, as described herein at least in relation to FIG. 5 and FIG. 6. In some embodiments, the changing a cooling capacity of a thermal management system includes changing at least one operating condition of the refrigeration system, such as a flow rate of working fluid through the refrigeration system and/or a compressor rate compressing the working fluid. In some embodiments, changing at least one operating condition of the refrigeration system includes changing an exhaust rate of the refrigeration system, such as enabling a fan or other active heat exhaustion device to exhaust heat from the refrigeration system to the ambient atmosphere or other heat sink.

In some embodiments, changing a cooling capacity of the thermal management system includes changing a flow path of the working fluid through the thermal management system. For example, the thermal management system may include a plurality of fluid circuits through one or more heat exchangers and/or include a dewar or storage tank of additional working fluid to provide additional thermal mass to the working fluid of the thermal management system. In some embodiments, changing a flow path of the working fluid includes flowing a second working fluid with a different boiling temperature and/or freezing temperature through at least a portion of the thermal management system. For example, the thermal management system may flow a first working fluid through a heat exchanger proximate to a processor core at a first processor temperature (e.g., ambient temperature) and flow a second working fluid through the heat exchanger proximate to the processor core at a second processor temperature (e.g., cryogenic temperature).

Selecting a computing component having a threshold voltage from a plurality of computing components of the same type based at least partially on a residual cooling capacity of the thermal management system downstream from the processor core at 830. In some embodiments, the transistors of the memory device(s), storage device(s), and/or other computing components of the computing system cooled by the thermal management system have various threshold voltages that allow the computing components to operate efficiently at different temperatures. For example, the computing system cooled by the thermal management system may include a plurality of memory devices with at least a first memory device of the plurality of memory devices having a first threshold voltage and at least a second memory device of the plurality of memory devices having a second threshold voltage. The first memory device operates more efficiently at a first memory temperature, and the second memory device operates more efficiently at a second memory temperature. Based at least partially on the residual cooling capacity of the thermal management system downstream from the processor core, the workload controller or other controller of the thermal management system selects a memory device of the plurality of memory devices.

In some examples, the computing system cooled by the thermal management system may include a plurality of storage devices with at least a first storage device of the plurality of storage devices having a first threshold voltage and at least a second storage device of the plurality of storage devices having a second threshold voltage. The first storage device operates more efficiently at a first storage device temperature, and the second storage device operates more efficiently at a second storage device temperature. Based at least partially on the residual cooling capacity of the thermal management system downstream from the processor core and/or the memory device(s), the workload controller or other controller of the thermal management system selects a storage device of the plurality of storage devices.

The method 820 further includes directing communication between the processor core and a selected computing component at 832. In some embodiments, communication between the processor core and the selected computing component is through a communication bus or a plurality of communication buses, such as described at least in relation to FIGS. 5 and 6 herein. In at least one example, the processor core communicates with the selected memory device(s) through a first communication bus, and the processor core communicates with the selected storage device(s) through a second communication bus. In at least one example, the processor core communicates with the selected memory device(s) through a communication bus, and the processor core communicates with the selected storage device(s) through the same communication bus.

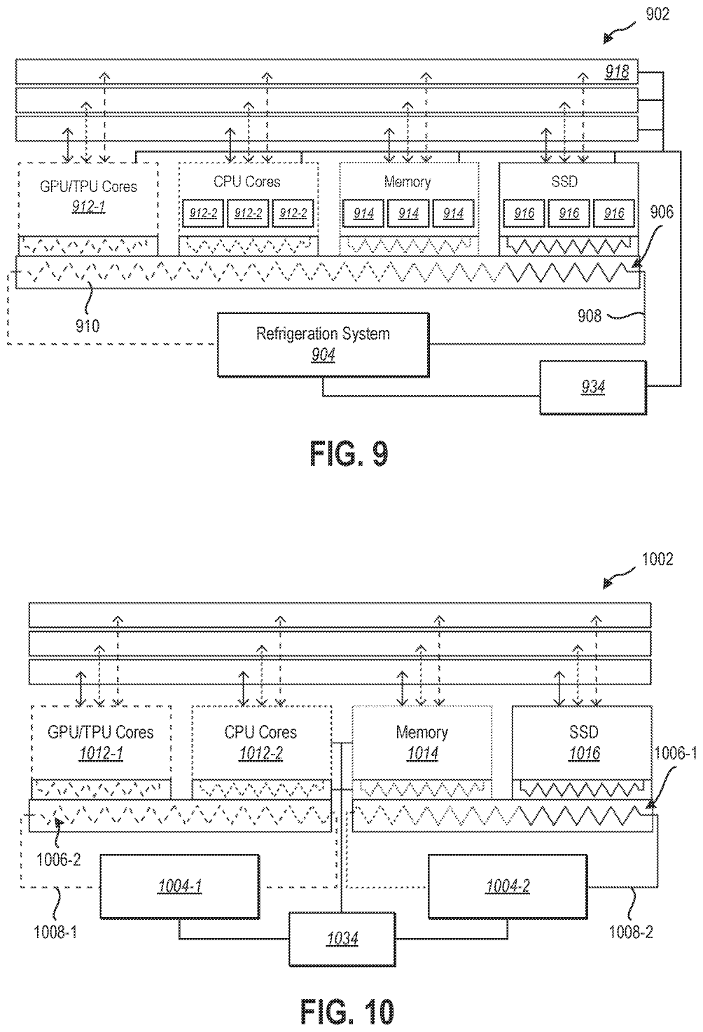

FIG. 9 is a schematic illustration of an embodiment of a variable-temperature thermal management system 902 with a plurality of selectable computing components of the same type. In some embodiments, the thermal management system 902 includes a refrigeration system 904 that exhausts heat from a working fluid 906 that circulates through one or more conduits 908 and/or heat exchangers 910. The thermal management system 902, in some embodiments, cools one or more of GPU cores 912-1, CPU cores 912-2, memory devices 914, storage devices 916 (such as solid-state drives), or other heat-generating components. The working fluid 906 receives heat from the heat-generating components, which increases the temperature of the working fluid 906 and reduces the temperature of the heat-generating components. The working fluid 906 circulates through the thermal management system 902 to the refrigeration system 904, which exhausts the heat from the working fluid 906.

In some embodiments, the computing components are in data communication with one another through a communication bus 918 or plurality of communication buses that allow each computing component of each type of computing component (e.g., GPU cores 912-1, CPU cores 912-2, memory devices 914, storage devices 916, etc.) to communicate with computing components of each other type of computing component. For example, the communication bus 918 allows each of the processing cores 912 to communicate with any to the memory devices 914 and any of the storage devices 916.

In some embodiments, different GPU cores 912-1 and/or CPU cores 912-2 have different threshold voltages (V_{T}), such that different GPU cores 912-1 and/or CPU cores 912-2 have different PPW efficiencies at different temperatures. In some embodiments, a GPU core 912-1 and/or CPU core 912-2 is selected based on a requested workload and the processing demands on the system. In some embodiments, the GPU core(s) 912-1 or the CPU core(s) 912-2 are prioritized for thermal management, depending on the requested workload. For example, a workload that is GPU processing intensive (such as a machine learning model training task) may cause the system to prioritize cryogenic cooling of the GPU cores 912-1 for increased performance, even when that cryogenic cooling increases power consumption from the thermal management system. In some embodiments, cryogenic cooling of a GPU core 912-1 requires the working fluid 906 be cooled to cryogenic temperatures and, even after receiving heat from the GPU core(s) 912-1, the working fluid 906 is still at cryogenic temperatures.

In some embodiments, the computing system can select a memory device 914 from a plurality of memory devices 914 and/or a storage device 916 from a plurality of storage devices 916 based at least partially on residual cooling capacity of the working fluid 906 after cooling the GPU core(s) 912-1 and the CPU core(s) 912-2. In at least one example, a requested workload is processing intensive, and a GPU core 912-1 is cryogenically cooled to a GPU temperature (T_{GPU}) and/or CPU core 912-2 is cryogenically cooled to a CPU temperature (T_{CPU}) by the thermal management system 902. The computing system selects a memory device 914 with a V_{T.MEM} based at least partially on the residual cooling capacity of the working fluid 906 after cooling the processing core(s) 912 that allows cooling of the memory device 914 to a memory temperature (T_{MEM}). By selecting a memory device 914 based on the T_{MEM} produced by the residual cooling capacity after cooling the processor core(s) 912 to T_{PROC}, the selected memory device(s) 914 have properties (e.g., V_{T.MEM}) that allow the selected memory device(s) 914 to operate efficiently (PPW) and/or quickly (e.g., bandwidth) at the T_{MEM}. Similarly, by selecting a storage device 916 based on the T_{SSD} produced by the residual cooling capacity after cooling the memory device(s) 914 to T_{MEM}, the selected storage device(s) 916 have properties (e.g., V_{T.SSD}) that allow the selected storage device(s) 916 to operate efficiently (PPW) and/or quickly (e.g., bandwidth) at the T_{SSD}.

In some embodiments, a requested workload is more CPU processing intensive than GPU processing intensive may prioritize cooling of the CPU to a selected T_{CPU}. In such a case, the GPU core(s) 912-1 are cooled enough to provide residual cooling capacity to achieve the selected T_{CPU}. A GPU core 912-1 is, in some embodiments, selected with a threshold voltage at a T_{GPU} that allows the efficient operation of the CPU at the selected T_{CPU}. The working fluid 906 has residual cooling capacity that is used to cool the memory device(s) 914 and/or the storage devices 916. The communication buses 918 allow communication between any of the computing components with other computing components of other types, allowing a GPU core 912-1 to communicate with the selected CPU core 912-2, the selected memory device(s) 914, and/or the selected storage device(s) 916 to dynamically configure computing systems that more or most efficiently operate at different temperatures.

In some embodiments, the types of computing components (e.g., GPU cores 912-1, CPU cores 912-2, memory devices 914, storage devices 916, etc.) are cooled in series with the computing components demanding the greatest cooling capacity positioned earlier in the series (i.e., closer to the refrigeration system 904) in flow direction of the working fluid 906 through the thermal management system 902. In some embodiments, different computing components within a type of computing component can have different operating temperatures or efficient operating temperatures. In some embodiments, the different operating temperatures or efficient operating temperatures can vary by requested workload.

A workload controller 934 is in data communication with at least some of the components of the computing system including, but not limited to, the GPU cores 912-1, CPU cores 912-2, memory devices 914, and storage devices 916. The workload controller 934 is further in data communication with the refrigeration system 904 and/or other components of the thermal management system 902, such as pumps, fans, or valves, that control the flow of working fluid 906 through the thermal management system 902. In some embodiments, the workload controller selects components from one or more of the component types (the GPU cores 912-1, CPU cores 912-2, memory devices 914, and storage devices 916) and directs communication therebetween through the communication bus(es) 918. Based at least partially on the selected components with associated operating temperatures and threshold voltages, the workload controller 934 instructs the refrigeration system 904 and/or other components of the thermal management system 902 to cool the selected components to the associated operating temperatures. For example, based on a targeted T_{GPU} of the GPU cores 912-1 for the workload demand, the workload controller 934 selects a CPU core 912-2 from the plurality of CPU cores 912-2 that has a threshold voltage appropriate for the T_{CPU} in series after the working fluid 906 receives the heat generated by the GPU cores 912-1 under the workload. In the serial cooling illustrated in FIG. 9, the workload controller 934 selects a memory device 914 from the plurality of memory devices 914 that has a threshold voltage appropriate for the T_{MEM} in series after the working fluid 906 receives the heat generated by the CPU cores 912-2 under the workload. In the serial cooling illustrated in FIG. 9, the workload controller 934 selects a storage device 916 from the plurality of storage devices 916 that has a threshold voltage appropriate for the T_{SSD} in series after the working fluid 906 receives the heat generated by the memory devices 914 under the workload.

FIG. 10 is a schematic illustration of an embodiment of a variable-temperature thermal management system 1002 with a plurality of cooling circuits. In some embodiments, the thermal management system 1002 includes a first conduit 1008-1 with a first refrigeration system 1004-1 that circulates a first working fluid 1006-1 therethrough, and the thermal management system 1002 includes a second conduit 1008-2 with a second refrigeration system 1004-2 that circulates a second working fluid 1006-2. In some embodiments, the thermal management system 1002 includes a first conduit 1008-1 and a second conduit 1008-2 that share a working fluid in the first conduit 1008-1 and the second conduit 1008-2 by adjusting one or more valves or pumps to adjust a ratio of flow rate or flow mass through the cooling circuits. In some embodiments, the first working fluid 1006-1 and the second working fluid 1006-2 are the same fluid (e.g., both liquid nitrogen). In some embodiments, the first working fluid 1006-1 and the second working fluid 1006-2 are different working fluids.

In some embodiments, at least one type of processing cores (e.g., GPU cores 1012-1, CPU cores 1012-2) is cooled by or in thermal communication with the first cooling circuit (i.e., first conduit 1008-1) and at least one other type of computing component (e.g., memory devices 1014, storage devices 1016) is cooled by or in thermal communication with the second cooling circuit (i.e., second conduit 1008-2). In some embodiments, the first cooling circuit provides thermal management to a plurality of computing components and the second cooling circuit provides thermal management to second plurality of computing components. A controller 1034 is in communication with the components of the computing system (e.g., GPU cores 1012-1, CPU cores 1012-2, memory devices 1014, storage devices 1016) to select components therefrom based on an obtained workload demand. In some embodiments, the controller 1034 is in communication with the components of the first cooling circuit and the second cooling circuit to provide thermal management and cooling for the selected components based at least partially on the associated operating temperatures of the selected components.

In at least some embodiments, variable temperature thermal management systems according to the present disclosure provide cryogenic cooling to some components of a computing system for increased performance and/or efficiency while providing less cooling to other components to limit the electrical power consumption of the thermal management system.

### Industrial Applicability

The present disclosure relates generally to systems and methods for cooling computing components. More particularly, the present disclosure relates to cooling of computing packages and components at a variety of temperatures. In some embodiments, a thermal management system allows for selective cryogenic cooling of some components of a computing system. In some embodiments, systems and methods according to the present disclosure can select computing components from a plurality of computing components wherein the selected computing components are selected based at least partially on a threshold voltage of the components and a current or expected component temperature during processing. Reconfigurable computing systems and variable cooling of the computing components allows a datacenter to adapt to the workload demands received to provide the highest performance and/or most efficient processing power.

In some embodiments, the thermal management system includes a refrigeration system that exhausts heat from a working fluid that circulates through one or more conduits and/or heat exchangers. The thermal management system, in some embodiments, cools one or more of processing cores, memory devices, storage devices (such as solid-state drives), or other heat-generating components. The working fluid receives heat from the heat-generating components, which increases the temperature of the working fluid and reduces the temperature of the heat-generating components. The working fluid circulates through the thermal management system to the refrigeration system, which exhausts the heat from the working fluid.

In some embodiments, the working fluid is or includes a two-phase working fluid that receives heat and changes state without a substantial change in temperature. In some embodiments, the working fluid is or includes liquid nitrogen. In some embodiments, the working fluid is or includes other fluids. For example, other working fluids 506 may be or include conventional refrigerants, liquid CO₂, liquefied hydrocarbons, liquid argon, liquid methane, gaseous nitrogen, gaseous helium, or combinations thereof.

In some embodiments, the computing components are in data communication with one another through a communication bus or plurality of communication buses that allow each computing component of each type of computing component (e.g., processing cores, memory devices, storage devices, etc.) to communicate with computing components of each other type of computing component. For example, the communication bus allows each of the processing cores to communicate with any of the memory devices and any of the storage devices.

In some embodiments, different processing cores of the plurality of processing cores have different threshold voltages (V_{T}), such that different processing cores have different PPW efficiencies at different temperatures. In some embodiments, a processing core is selected based on a requested workload and the processing demands on the system. For example, a workload that is highly processing intensive (such as a machine learning model training task) justifies cryogenic cooling of the processing core(s) for increased performance, even when that cryogenic cooling increases power consumption from the thermal management system. In some embodiments, cryogenic cooling of a processing core requires the working fluid be cooled to cryogenic temperatures and, even after receiving heat from the processing core(s), the working fluid is still at cryogenic temperatures. The working fluid has residual cooling capacity that is used to cool the memory device(s) and/or the storage devices.

As will described in more detail herein, in some embodiments, the computing system can select a memory device from a plurality of memory devices and/or a storage device from a plurality of storage devices based at least partially on residual cooling capacity of the working fluid after cooling the processing core(s). In at least one example, a requested workload is processing intensive, and a processing core is cryogenically cooled to a processor temperature (T_{PROC}) by the thermal management system. The computing system selects a memory device with a V_{T.MEM} based at least partially on the residual cooling capacity of the working fluid after cooling the processing core(s) that allows cooling of the memory device to a memory temperature (T_{MEM}). By selecting a memory device based on the T_{MEM} produced by the residual cooling capacity after cooling the processor core(s) to T_{PROC}, the selected memory device(s) have properties (e.g., V_{T.MEM}) that allow the selected memory device(s) to operate efficiently (e.g., PPW) and/or quickly (e.g., bandwidth) at the T_{MEM}. Similarly, by selecting a storage device based on the T_{SSD} produced by the residual cooling capacity after cooling the memory device(s) to T_{MEM}, the selected storage device(s) have properties (e.g., V_{T.SSD}) that allow the selected storage device(s) to operate efficiently (e.g., PPW) and/or quickly (e.g., bandwidth) at the T_{SSD}. The communication buses allow communication between any of the computing components with other computing components of other types, allowing a processing core to communicate with the selected memory device(s) and/or selected storage device(s) to dynamically configure computing systems that more or most efficiently operate at different temperatures.

In some embodiments, the types of computing components (e.g., processing cores, memory devices, storage devices, etc.) are cooled in series with the computing components demanding the greatest cooling capacity positioned earlier in the series (i.e., closer to the refrigeration system) in flow direction of the working fluid through the thermal management system. In some embodiments, different computing components within a type of computing component can have different operating temperatures or efficient operating temperatures. In some embodiments, the different operating temperatures or efficient operating temperatures can vary by requested workload.

In some embodiments, the thermal management system includes a refrigeration system that exhausts heat from a working fluid that circulates through one or more conduits and/or heat exchangers. The thermal management system, in some embodiments, cools one or more of GPU cores, CPU cores, memory devices, storage devices (such as solid-state drives), or other heat-generating components. The working fluid receives heat from the heat-generating components, which increases the temperature of the working fluid and reduces the temperature of the heat-generating components. The working fluid circulates through the thermal management system to the refrigeration system, which exhausts the heat from the working fluid.

In some embodiments, the computing components are in data communication with one another through a communication bus or plurality of communication buses that allow each computing component of each type of computing component (e.g., GPU cores, CPU cores, memory devices, storage devices, etc.) to communicate with computing components of each other type of computing component. For example, the communication bus allows each of the processing cores to communicate with any to the memory devices and any of the storage devices.

In some embodiments, different GPU cores and/or CPU cores have different threshold voltages (V_{T}), such that different GPU cores and/or CPU cores have different PPW efficiencies at different temperatures. In some embodiments, a GPU core and/or CPU core is selected based on a requested workload and the processing demands on the system. In some embodiments, the GPU core(s) or the CPU core(s) are prioritized over one another for thermal management, depending on the requested workload. For example, a workload that is GPU processing intensive (such as a machine learning model training task) may cause the system to prioritize cryogenic cooling of the GPU cores for increased performance, even when that cryogenic cooling increases power consumption from the thermal management system. In some embodiments, cryogenic cooling of a GPU core requires the working fluid be cooled to cryogenic temperatures and, even after receiving heat from the GPU core(s), the working fluid is still at cryogenic temperatures.

In some embodiments, a requested workload that is more CPU processing intensive than GPU processing intensive may prioritize cooling of the CPU to a selected T_{CPU}. In such a case, the GPU core(s) is cooled enough to provide residual cooling capacity to achieve the selected T_{CPU}. A GPU core is, in some embodiments, selected with a threshold voltage at a T_{GPU} that allows the efficient operation of the CPU at the selected T_{CPU}. The working fluid has residual cooling capacity that is used to cool the memory device(s) and/or the storage devices. The communication buses allow communication between any of the computing components with other computing components of other types, allowing a GPU core to communicate with the selected CPU core, the selected memory device(s), and/or the selected storage device(s) to dynamically configure computing systems that more or most efficiently operate at different temperatures.

In some embodiments, the types of computing components (e.g., GPU cores, CPU cores, memory devices, storage devices, etc.) are cooled in series with the computing components demanding the greatest cooling capacity positioned earlier in the series (i.e., closer to the refrigeration system) in flow direction of the working fluid through the thermal management system. In some embodiments, different computing components within a type of computing component can have different operating temperatures or efficient operating temperatures. In some embodiments, the different operating temperatures or efficient operating temperatures can vary by requested workload.

In some embodiments, a method of operating a datacenter includes obtaining a workload demand. In some embodiments, the workload demand is obtained from an allocator or other workload management controller. In some embodiments, the workload demand is received from an allocator or other workload management controller in the datacenter, such as local to the computing devices processing the workload and cooled by a variable-temperature thermal management system. In some embodiments, the workload demand is received from an allocator or other workload management controller external to the datacenter, such as remote to the computing devices processing the workload and cooled by a variable-temperature thermal management system. In some embodiments, the allocator or other workload management controller is located in another datacenter or that is in data communication with the datacenter or co-location including the computing devices processing the workload and cooled by a variable-temperature thermal management system.

In some embodiments, the workload demand is obtained by a workload controller, as will be described in more detail herein. The workload controller is, in some embodiments, in data communication with at least some of the computing components of the datacenter. The workload controller is, in some embodiments, in data communication with at least some components of the variable-temperature thermal management system, such as a refrigeration system, heat exchangers, one or more valves, etc.

The method further includes determining at least a processor temperature based at least partially on the workload demand. In some embodiments, the allocator or other workload management controller provides or determines the processor temperature. In some embodiments, the workload controller provides or determines the processor temperature. For example, determining at least a processor temperature based at least partially on the workload demand may include comparing the workload demand or workload demand type to a table or other file of expected processing loads. In some embodiments, a processor temperature is determined at least partially on a known or expected workload duration. For example, cryogenically-cooling the processor core(s) may provide greater efficiency and/or speed gains when the duration of the workload is longer, as the initial cooling of the processor core(s) to the cryogenic temperatures consumes power. In some embodiments, the processor temperature is determined at least partially on a known or expected processor load. For example, the computing system may include GPUs that have a greater PPW gain at cryogenic temperatures than CPUs of the computing system. The processor temperature may be determined at least partially on the PPW efficiency and/or processing speed gains of the type of processors.

In some embodiments, the workload demand or workload demand type is known or expected to place a greater computational demand on a GPU or on a CPU of the computing system. In at least one example, the method may include determining a first processor temperature for a GPU-intensive workload while a CPU-intensive workload may be determined to prioritize a different processor temperature. In some embodiments, determining at least a processor temperature based at least partially on the workload demand includes determining a GPU temperature. In some embodiments, determining at least a processor temperature based at least partially on the workload demand includes determining a CPU temperature. In some embodiments, determining at least a processor temperature based at least partially on the workload demand includes selecting a lower processor temperature of the CPU temperature and the GPU temperature. In some embodiments, determining at least a processor temperature based at least partially on the workload demand includes determining a memory device temperature. For example, the memory device temperature may be determined based at least partially on a residual cooling capacity in series from the processor temperature. In some embodiments, determining at least a processor temperature based at least partially on the workload demand includes determining a storage device temperature. For example, the storage device temperature may be determined based at least partially on a residual cooling capacity in series from the processor temperature and/or memory device temperature.

The method further includes changing a cooling capacity of a thermal management system at a processor core based at least partially on the processor temperature. The thermal management system includes a refrigeration system that exhausts heat from a working fluid, as described herein. In some embodiments, the changing a cooling capacity of a thermal management system includes changing at least one operating condition of the refrigeration system, such as a flow rate of working fluid through the refrigeration system and/or a compressor rate compressing the working fluid. In some embodiments, changing at least one operating condition of the refrigeration system includes changing an exhaust rate of the refrigeration system, such as enabling a fan or other active heat exhaustion device to exhaust heat from the refrigeration system to the ambient atmosphere or other heat sink.

In some embodiments, changing a cooling capacity of the thermal management system includes changing a flow path of the working fluid through the thermal management system. For example, the thermal management system may include a plurality of fluid circuits through one or more heat exchangers and/or include a dewar or storage tank of additional working fluid to provide additional thermal mass to the working fluid of the thermal management system. In some embodiments, changing a flow path of the working fluid includes flowing a second working fluid with a different boiling temperature and/or freezing temperature through at least a portion of the thermal management system. For example, the thermal management system may flow a first working fluid through a heat exchanger proximate to a processor core at a first processor temperature (e.g., ambient temperature) and flow a second working fluid through the heat exchanger proximate to the processor core at a second processor temperature (e.g., cryogenic temperature).

In some embodiments, the method optionally includes selecting a processor core having a processor threshold voltage from a plurality of processor cores based at least partially on the processor temperature. In some embodiments, the processor temperature is determined at least partially based on a processor threshold voltage. The processor threshold voltage is a property of the processor core(s). A lower processor temperature allows for a lower threshold voltage, which, in turn, allows for a lower supply voltage and greater PPW efficiency. In some examples, the same processor core with a lower threshold voltage does not operate efficiently at a higher processor temperature, such as at ambient temperature. The determined and/or selected processor temperature, therefore, allows the workload controller or other controller to select one or more processor cores having a threshold voltage based at least partially on the processor temperature.

In some embodiments, the method includes determining a GPU temperature. In such examples, selecting a processor core having a threshold voltage based on the processor temperature includes selecting a GPU core having a GPU threshold voltage based on the GPU temperature. In some examples, the method includes selecting a CPU core based at least partially on the residual cooling capacity when the CPU core is after the GPU core in series. In some examples, the method includes selecting a CPU core based at least partially on the residual cooling capacity to achieve the GPU temperature when the GPU core is after the CPU core in series.

In some embodiments, the method includes selecting other computing devices based at least partially on residual cooling capacity after the targeted processor temperature. In some embodiments, the method includes obtaining a workload demand. In some embodiments, the workload demand is obtained from an allocator or other workload management controller. In some embodiments, the workload demand is received from an allocator or other workload management controller in the datacenter, such as local to the computing devices processing the workload and cooled by a variable-temperature thermal management system. In some embodiments, the workload demand is received from an allocator or other workload management controller external to the datacenter, such as remote to the computing devices processing the workload and cooled by a variable-temperature thermal management system. In some embodiments, the allocator or other workload management controller is located in another datacenter or that is in data communication with the datacenter or co-location including the computing devices processing the workload and cooled by a variable-temperature thermal management system.

In some embodiments, the workload demand is obtained by a workload controller, as will be described in more detail herein. The workload controller is, in some embodiments, in data communication with at least some of the computing components of the datacenter. The workload controller is, in some embodiments, in data communication with at least some components of the variable-temperature thermal management system, such as a refrigeration system, heat exchangers, one or more valves, etc.

The method further includes determining at least a processor temperature based at least partially on the workload demand. In some embodiments, the allocator or other workload management controller provides or determines the processor temperature. In some embodiments, the workload controller provides or determines the processor temperature. For example, determining at least a processor temperature based at least partially on the workload demand may include comparing the workload demand or workload demand type to a table or other file of expected processing loads. In some embodiments, a processor temperature is determined at least partially on a known or expected workload duration. For example, cryogenically-cooling the processor core(s) may provide greater efficiency and/or speed gains when the duration of the workload is longer, as the initial cooling of the processor core(s) to the cryogenic temperatures consumes power. In some embodiments, the processor temperature is determined at least partially on a known or expected processor load. For example, the computing system may include GPUs that have a greater PPW gain at cryogenic temperatures than CPUs of the computing system. The processor temperature may be determined at least partially on the PPW efficiency and/or processing speed gains of the type of processors.

In some embodiments, the workload demand or workload demand type is known or expected to place a greater computational demand on a GPU or on a CPU of the computing system. In at least one example, the method may include determining a first processor temperature for a GPU-intensive workload while a CPU-intensive workload may be determined to prioritize a different processor temperature. In some embodiments, determining at least a processor temperature based at least partially on the workload demand includes determining a GPU temperature. In some embodiments, determining at least a processor temperature based at least partially on the workload demand includes determining a CPU temperature. In some embodiments, determining at least a processor temperature based at least partially on the workload demand includes selecting a lower processor temperature of the CPU temperature and the GPU temperature. In some embodiments, determining at least a processor temperature based at least partially on the workload demand includes determining a memory device temperature. For example, the memory device temperature may be determined based at least partially on a residual cooling capacity in series from the processor temperature. In some embodiments, determining at least a processor temperature based at least partially on the workload demand includes determining a storage device temperature. For example, the storage device temperature may be determined based at least partially on a residual cooling capacity in series from the processor temperature and/or memory device temperature.

In some embodiments, the workload demand or workload demand type is known or expected to place a greater computational demand on a GPU or on a CPU of the computing system. In at least one example, the method may include determining a first processor temperature for a GPU-intensive workload while a CPU-intensive workload may be determined to prioritize a different processor temperature. In some embodiments, determining at least a processor temperature based at least partially on the workload demand includes determining a GPU temperature. In some embodiments, determining at least a processor temperature based at least partially on the workload demand includes determining a CPU temperature. In some embodiments, determining at least a processor temperature based at least partially on the workload demand includes selecting a lower processor temperature of the CPU temperature and the GPU temperature. In some embodiments, determining at least a processor temperature based at least partially on the workload demand includes determining a memory device temperature. For example, the memory device temperature may be determined based at least partially on a residual cooling capacity in series from the processor temperature. In some embodiments, determining at least a processor temperature based at least partially on the workload demand includes determining a storage device temperature. For example, the storage device temperature may be determined based at least partially on a residual cooling capacity in series from the processor temperature and/or memory device temperature.

The method further includes changing a cooling capacity of a thermal management system at a processor core based at least partially on the processor temperature. The thermal management system includes a refrigeration system that exhausts heat from a working fluid, as described herein. In some embodiments, the changing a cooling capacity of a thermal management system includes changing at least one operating condition of the refrigeration system, such as a flow rate of working fluid through the refrigeration system and/or a compressor rate compressing the working fluid. In some embodiments, changing at least one operating condition of the refrigeration system includes changing an exhaust rate of the refrigeration system, such as enabling a fan or other active heat exhaustion device to exhaust heat from the refrigeration system to the ambient atmosphere or other heat sink.

In some embodiments, changing a cooling capacity of the thermal management system includes changing a flow path of the working fluid through the thermal management system. For example, the thermal management system may include a plurality of fluid circuits through one or more heat exchangers and/or include a dewar or storage tank of additional working fluid to provide additional thermal mass to the working fluid of the thermal management system. In some embodiments, changing a flow path of the working fluid includes flowing a second working fluid with a different boiling temperature and/or freezing temperature through at least a portion of the thermal management system. For example, the thermal management system may flow a first working fluid through a heat exchanger proximate to a processor core at a first processor temperature (e.g., ambient temperature) and flow a second working fluid through the heat exchanger proximate to the processor core at a second processor temperature (e.g., cryogenic temperature).

Selecting a computing component having a threshold voltage from a plurality of computing components of the same type based at least partially on a residual cooling capacity of the thermal management system downstream from the processor core. In some embodiments, the transistors of the memory device(s), storage device(s), and/or other computing components of the computing system cooled by the thermal management system have various threshold voltages that allow the computing components to operate efficiently at different temperatures. For example, the computing system cooled by the thermal management system may include a plurality of memory devices with at least a first memory device of the plurality of memory devices having a first threshold voltage and at least a second memory device of the plurality of memory devices having a second threshold voltage. The first memory device operates more efficiently at a first memory temperature, and the second memory device operates more efficiently at a second memory temperature. Based at least partially on the residual cooling capacity of the thermal management system downstream from the processor core, the workload controller or other controller of the thermal management system selects a memory device of the plurality of memory devices.

In some examples, the computing system cooled by the thermal management system may include a plurality of storage devices with at least a first storage device of the plurality of storage devices having a first threshold voltage and at least a second storage device of the plurality of storage devices having a second threshold voltage. The first storage device operates more efficiently at a first storage device temperature, and the second storage device operates more efficiently at a second storage device temperature. Based at least partially on the residual cooling capacity of the thermal management system downstream from the processor core and/or the memory device(s), the workload controller or other controller of the thermal management system selects a storage device of the plurality of storage devices.

The method further includes directing communication between the processor core and a selected computing component. In some embodiments, communication between the processor core and the selected computing component is through a communication bus or a plurality of communication buses, such as described herein. In at least one example, the processor core communicates with the selected memory device(s) through a first communication bus, and the processor core communicates with the selected storage device(s) through a second communication bus. In at least one example, the processor core communicates with the selected memory device(s) through a communication bus, and the processor core communicates with the selected storage device(s) through the same communication bus.

In some embodiments, a variable-temperature thermal management system includes a plurality of selectable computing components of the same type. In some embodiments, the thermal management system includes a refrigeration system that exhausts heat from a working fluid that circulates through one or more conduits and/or heat exchangers. The thermal management system, in some embodiments, cools one or more of GPU cores, CPU cores, memory devices, storage devices (such as solid-state drives), or other heat-generating components. The working fluid receives heat from the heat-generating components, which increases the temperature of the working fluid and reduces the temperature of the heat-generating components. The working fluid circulates through the thermal management system to the refrigeration system, which exhausts the heat from the working fluid.

In some embodiments, the computing components are in data communication with one another through a communication bus or plurality of communication buses that allow each computing component of each type of computing component (e.g., GPU cores, CPU cores, memory devices, storage devices, etc.) to communicate with computing components of each other type of computing component. For example, the communication bus allows each of the processing cores to communicate with any to the memory devices and any of the storage devices.

In some embodiments, different GPU cores and/or CPU cores have different threshold voltages (V_{T}), such that different GPU cores and/or CPU cores have different PPW efficiencies at different temperatures. In some embodiments, a GPU core and/or CPU core is selected based on a requested workload and the processing demands on the system. In some embodiments, the GPU core(s) or the CPU core(s) are prioritized over one another for thermal management, depending on the requested workload. For example, a workload that is GPU processing intensive (such as a machine learning model training task) may cause the system to prioritize cryogenic cooling of the GPU cores for increased performance, even when that cryogenic cooling increases power consumption from the thermal management system. In some embodiments, cryogenic cooling of a GPU core requires the working fluid be cooled to cryogenic temperatures and, even after receiving heat from the GPU core(s), the working fluid is still at cryogenic temperatures.

In some embodiments, the computing system can select a memory device from a plurality of memory devices and/or a storage device from a plurality of storage devices based at least partially on residual cooling capacity of the working fluid after cooling the GPU core(s) and the CPU core(s). In at least one example, a requested workload is processing intensive, and a GPU core is cryogenically cooled to a GPU temperature (T_{GPU}) and/or CPU core is cryogenically cooled to a CPU temperature (T_{CPU}) by the thermal management system. The computing system selects a memory device with a V_{T.MEM} based at least partially on the residual cooling capacity of the working fluid after cooling the processing core(s) that allows cooling of the memory device to a memory temperature (T_{MEM}). By selecting a memory device based on the T_{MEM} produced by the residual cooling capacity after cooling the processor core(s) to T_{PROC}, the selected memory device(s) have properties (e.g., V_{T.MEM}) that allow the selected memory device(s) to operate efficiently (e.g., PPW) and/or quickly (e.g., bandwidth) at the T_{MEM}. Similarly, by selecting a storage device based on the T_{SSD} produced by the residual cooling capacity after cooling the memory device(s) to T_{MEM}, the selected storage device(s) have properties (e.g., V_{T.SSD}) that allow the selected storage device(s) to operate efficiently (PPW) and/or quickly (e.g., bandwidth) at the T_{SSD}.

In some embodiments, a requested workload is more CPU processing intensive than GPU processing intensive may prioritize cooling of the CPU to a selected T_{CPU}. In such a case, the GPU core(s) are cooled enough to provide residual cooling capacity to achieve the selected T_{CPU}. A GPU core 912-1 is, in some embodiments, selected with a threshold voltage at a T_{GPU} that allows the efficient operation of the CPU at the selected T_{CPU}. The working fluid 906 has residual cooling capacity that is used to cool the memory device(s) 914 and/or the storage devices 916. The communication buses 918 allow communication between any of the computing components with other computing components of other types, allowing a GPU core 912-1 to communicate with the selected CPU core 912-2, the selected memory device(s) 914, and/or the selected storage device(s) 916 to dynamically configure computing systems that more or most efficiently operate at different temperatures.

In some embodiments, the types of computing components (e.g., GPU cores, CPU cores, memory devices, storage devices, etc.) are cooled in series with the computing components demanding the greatest cooling capacity positioned earlier in the series (i.e., closer to the refrigeration system) in flow direction of the working fluid through the thermal management system. In some embodiments, different computing components within a type of computing component can have different operating temperatures or efficient operating temperatures. In some embodiments, the different operating temperatures or efficient operating temperatures can vary by requested workload.

A workload controller is in data communication with at least some of the components of the computing system including, but not limited to, the GPU cores, CPU cores, memory devices, and storage devices. The workload controller is further in data communication with the refrigeration system and/or other components of the thermal management system, such as pumps, fans, or valves, that control the flow of working fluid through the thermal management system. In some embodiments, the workload controller selects components from one or more of the component types (the GPU cores, CPU cores, memory devices, and storage devices) and directs communication therebetween through the communication bus(es). Based at least partially on the selected components with associated operating temperatures and threshold voltages, the workload controller instructs the refrigeration system and/or other components of the thermal management system to cool the selected components to the associated operating temperatures. For example, based on a targeted T_{GPU} of the GPU cores for the workload demand, the workload controller selects a CPU core from the plurality of CPU cores that has a threshold voltage appropriate for the T_{CPU} in series after the working fluid receives the heat generated by the GPU cores under the workload. In some examples, the workload controller selects a memory device from the plurality of memory devices that has a threshold voltage appropriate for the T_{MEM} in series after the working fluid receives the heat generated by the CPU cores under the workload. In some examples, the workload controller selects a storage device from the plurality of storage devices that has a threshold voltage appropriate for the T_{SSD} in series after the working fluid receives the heat generated by the memory devices under the workload.

In some embodiments, the thermal management system includes a first conduit with a first refrigeration system that circulates a first working fluid therethrough, and the thermal management system includes a second conduit with a second refrigeration system that circulates a second working fluid. In some embodiments, the thermal management system includes a first conduit and a second conduit that share a working fluid in the first conduit and the second conduit by adjusting one or more valves or pumps to adjust a ratio of flow rate or flow mass through the cooling circuits. In some embodiments, the first working fluid and the second working fluid are the same fluid (e.g., both liquid nitrogen). In some embodiments, the first working fluid and the second working fluid are different working fluids.

In some embodiments, at least one type of processing cores (e.g., GPU cores, CPU cores) is cooled by or in thermal communication with the first cooling circuit (i.e., first conduit) and at least one other type of computing component (e.g., memory devices, storage devices) is cooled by or in thermal communication with the second cooling circuit (i.e., second conduit). In some embodiments, the first cooling circuit provides thermal management to a plurality of computing components and the second cooling circuit provides thermal management to second plurality of computing components. A controller is in communication with the components of the computing system (e.g., GPU cores, CPU cores, memory devices, storage devices) to select components therefrom based on an obtained workload demand. In some embodiments, the controller is in communication with the components of the first cooling circuit and the second cooling circuit to provide thermal management and cooling for the selected components based at least partially on the associated operating temperatures of the selected components.

In at least some embodiments, variable temperature thermal management systems according to the present disclosure provide cryogenic cooling to some components of a computing system for increased performance and/or efficiency while providing less cooling to other components to limit the electrical power consumption of the thermal management system.

The present disclosure relates to systems and methods for cooling of computing components in a datacenter according to at least the examples provided in the sections below:

Clause 1. A thermal management system comprising: a processor core; a memory device; a conduit having a flow direction and configured to receive heat from the processor core and the memory device a refrigeration system in series; a working fluid located in the conduit and configured to receive the heat through the conduit to cool the processor core; a refrigeration system configured to exhaust heat from the working fluid and cool the working fluid to a lower-then-ambient temperature; and a workload controller in data communication with the refrigeration system and configured to instruct the refrigeration system to cool the processor core to a processor temperature based at least partially on a workload demand.

Clause 2. The thermal management system of clause 1, further comprising a storage device configured to exhaust heat to the conduit and the working fluid after the memory device in the flow direction of the conduit.

Clause 3. The thermal management system of clause 1, wherein the working fluid is liquid nitrogen.

Clause 4. The thermal management system of clause 1, wherein the processor core is a graphical processing unit (GPU) core.

Clause 5. The thermal management system of clause 1, wherein the processor core is a central processing unit (CPU) core.

Clause 6. The thermal management system of clause 1, wherein the memory device is a first memory device of a plurality of memory devices with different threshold voltages for operation at different temperatures.

Clause 7. The thermal management system of clause 1, wherein the processor core is a processor core of a plurality of processor cores with different threshold voltages for operation at different temperatures.

Clause 8. The thermal management system of clause 1, wherein the working fluid is a first working fluid and further comprising a second conduit having a second working fluid, wherein the second conduit is configured to receive heat from at least the memory device.

Clause 9. The thermal management system of clause 8, wherein the second working fluid is different from the first working fluid.

Clause 10. The thermal management system of clause 8, further comprising a second refrigeration system configured to cool the second working fluid, wherein the second refrigeration system is in data communication with the workload controller.

Clause 11. A method of operating a datacenter, the method comprising: obtaining a workload demand; determining at least a processor temperature based at least partially on the workload demand; changing a cooling capacity of a refrigeration system at a processor core based at least partially on the processor temperature; and selecting the processor core having a threshold voltage from a plurality of processor cores based at least partially on the processor temperature.

Clause 12. The method of clause 11, wherein the workload demand is obtained from an allocator external to the datacenter.

Clause 13. The method of clause 11, wherein determining a processor temperature includes prioritizing thermal management of a GPU core over a CPU core based at least partially on the workload demand.

Clause 14. The method of clause 11, wherein changing a cooling capacity of a refrigeration system includes changing a flow rate of working fluid through a conduit proximate to the processor core.

Clause 15. The method of clause 11, wherein selecting the processor core includes selecting at least one GPU core and at least one CPU core from the plurality of processor cores.

Clause 16. The method of clause 15, wherein the at least one CPU core has a CPU temperature higher than a GPU temperature of the at least one GPU core.

Clause 17. The method of clause 11, wherein changing a cooling capacity includes changing a thermal mass of a working fluid.

Clause 18. A method of operating a datacenter, the method comprising: obtaining a workload demand; determining at least a processor temperature based at least partially on the workload demand; changing a cooling capacity of a refrigeration system at a processor core based at least partially on the processor temperature; selecting a computing component having a threshold voltage from a plurality of computing components of a same type based at least partially on a residual cooling capacity of a working fluid downstream in a flow direction of the working fluid from the processor core; and directing communication between the processor core and a selected computing component.

Clause 19. The method of clause 18, wherein the selected computing component is a memory device.

Clause 20. The method of clause 18, wherein the selected computing component is a storage device.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A thermal management system comprising:
a processor core;
a memory device;
a conduit having a flow direction and configured to receive heat from the processor core and the memory device a refrigeration system in series;
a working fluid located in the conduit and configured to receive the heat through the conduit to cool the processor core;
a refrigeration system configured to exhaust heat from the working fluid and cool the working fluid to a colder-than-ambient temperature; and
a workload controller in data communication with the refrigeration system and configured to instruct the refrigeration system to cool the processor core to a processor temperature based at least partially on a workload demand.

2. The thermal management system of claim 1, further comprising a storage device configured to exhaust heat to the conduit and the working fluid after the memory device in the flow direction of the conduit.

3. The thermal management system of claim 1, wherein the working fluid is liquid nitrogen.

4. The thermal management system of claim 1, wherein the processor core is a graphical processing unit (GPU) core.

5. The thermal management system of claim 1, wherein the processor core is a central processing unit (CPU) core.

6. The thermal management system of claim 1, wherein the memory device is a first memory device of a plurality of memory devices with different threshold voltages for operation at different temperatures.

7. The thermal management system of claim 1, wherein the processor core is a processor core of a plurality of processor cores with different threshold voltages for operation at different temperatures.

8. The thermal management system of claim 1, wherein the working fluid is a first working fluid and further comprising a second conduit having a second working fluid, wherein the second conduit is configured to receive heat from at least the memory device.

9. The thermal management system of claim 8, wherein the second working fluid is different from the first working fluid.

10. The thermal management system of claim 8, further comprising a second refrigeration system configured to cool the second working fluid, wherein the second refrigeration system is in data communication with the workload controller.

11. A method of operating a datacenter, the method comprising:
obtaining a workload demand;
determining at least a processor temperature based at least partially on the workload demand;
changing a cooling capacity of a refrigeration system at a processor core based at least partially on the processor temperature; and
selecting the processor core having a threshold voltage from a plurality of processor cores based at least partially on the processor temperature.

12. The method of claim 11, wherein the workload demand is obtained from an allocator external to the datacenter.

13. The method of claim 11, wherein determining a processor temperature includes prioritizing thermal management of a GPU core over a CPU core based at least partially on the workload demand.

14. The method of claim 11, wherein changing a cooling capacity of a refrigeration system includes changing a flow rate of working fluid through a conduit proximate to the processor core.

15. The method of claim 11, wherein selecting the processor core includes selecting at least one GPU core and at least one CPU core from the plurality of processor cores.

16. The method of claim 15, wherein the at least one CPU core has a CPU temperature higher than a GPU temperature of the at least one GPU core.

17. The method of claim 11, wherein changing a cooling capacity includes changing a thermal mass of a working fluid.

18. A method of operating a datacenter, the method comprising:
obtaining a workload demand;
determining at least a processor temperature based at least partially on the workload demand;
changing a cooling capacity of a refrigeration system at a processor core based at least partially on the processor temperature;
selecting a computing component having a threshold voltage from a plurality of computing components of a same type based at least partially on a residual cooling capacity of a working fluid downstream in a flow direction of the working fluid from the processor core; and
directing communication between the processor core and a selected computing component.

19. The method of claim 18, wherein the selected computing component is a memory device.

20. The method of claim 18, wherein the selected computing component is a storage device.
